(19) United States
(12) Patent Application Publication
(10) Pub. No.: US 2013/0011941 A1
(43) Pub. Date: Jan. 10, 2013

(54) BOND LINE THICKNESS CONTROL FOR DIE ATTACHMENT

(75) Inventors: Man Wai CHAN, Kwai Chung (CN); Shiu Kei LAM, Kwai Chung (HK); Wan Yin YAU, Kwai Chung (HK); Kwok Yuen CHEUNG, Kwai Chung (HK)

(73) Assignee: ASM Technology Singapore Pte, Ltd.

(21) Appl. No.: 13/177,906

(22) Filed: Jul. 7, 2011

(51) Int. Cl. H01L 21/50; B32B 37/12

(52) U.S. Cl. 438/15; 156/356; 156/378; 257/E21.499

(57) ABSTRACT

A semiconductor die is attached onto a substrate on a process platform during manufacturing of a semiconductor package. A dispenser dispenses an adhesive onto the substrate, and the semiconductor die is bonded onto the adhesive which has been dispensed onto the substrate with a bonding tool. Thereafter, a bond line thickness between a bottom surface of the semiconductor die and a top surface of the substrate on the process platform is measured using a measuring device.

### FIELD OF THE INVENTION

The present invention relates to the field of semiconductor assembly and packaging, and more particularly, to the attachment of a semiconductor chip or die onto a substrate using adhesive.

### BACKGROUND AND PRIOR ART

The semiconductor die-attach process is one of the steps involved in semiconductor device manufacturing, and it involves attaching semiconductor dice to specific bond pads on a lead frame. The attachment is usually achieved by first dispensing an adhesive material (e.g. epoxy) onto the bond pads, and then pressing the dice into the adhesive material with a certain pressure.

Thermal treatment with oven cure is thereafter performed to solidify the adhesive and secure the dice onto the lead frame after the die-attach process. The cured dice are then electrically coupled to the bond pads via connecting bonding wires between the dice and the conductive leads on the lead frame. The cured die and the bonding wires are finally encapsulated in a protective case using a molding material, such as thermoplastic resin or ceramic, to complete the packaging of the semiconductor device.

FIG. 1 is a cross sectional view of a die 101 attached onto a lead frame 103 by an adhesive 102. The thickness of the adhesive 102 between the bottom of the die 101 and the surface of the bond pad on the lead frame 103 is referred as the bond line thickness (“BLT”). In FIG. 1, the BLT is illustrated as the height t₁, whereas a thickness of the die 101 is indicated as t₂. The BLT (t₁) can be calculated by subtracting a height of the surface of the bond pad of the lead frame 103 and the thickness of the die 101 (t₂) from a height of the top surface of the die 101.

As the adhesive 102 is used for attaching the die 101 onto the lead frame 103, the bond line cannot be too thin. After the die 101 is cured so that the adhesive 102 hardens, the die 101 is still subjected to thermal expansion and contraction at subsequent packaging procedures. If the bond line is too thin, since the thermal expansion and contraction may happen at different rates between the die 101 and adhesive 102, there may not be sufficient adhesive 102 under the die 101 to cater for such expansion or contraction of the die 101 and adhesive 102. This may lead to fractures and cracks in the die 101. The die 101 may also become detached from the adhesive 102 in some severe cases.

On the other hand, the bond line cannot be too thick either. If too much adhesive 102 is present, the adhesive 102 may seep out and contaminate the surface of the die 101. Amongst other things, this may result in poor wire bonding quality when electrical wire connections are made between the die 101 and the lead frame 103. Moreover, the problems described above inevitably deteriorate the reliability and performance of the packaged semiconductor device. Hence, the bond line thickness has to be carefully controlled within an appropriate range during the die-attach process.

Accurate measurement of bond line thickness is necessary in order to achieve precise bond line thickness control. A conventional bond line thickness measurement method is cross-sectioning, which requires a cured die to be cut open along a line. Then, the cross sectioned die and adhesive are put under a microscope for measuring the bond line thickness. Cross-sectioning is a destructive method, and the cutting procedure makes it time-consuming.

As online feedback is difficult to achieve, there have been approaches proposed to control the bond line thickness by designing special lead frames. In US Patent Publication number 2009/0115039 A1 entitled “High Bond Line Thickness for Semiconductor Devices”, it is proposed to create boundary features at the edges of a bond pad on a lead frame. When adhesive is dispensed onto the bond pad, the adhesive is confined within the pad area defined by the boundary features and accumulated. This ensures that the pad area has enough adhesive to create a certain thickness for the bond line. Further, U.S. Pat. No. 5,214,307 entitled “Lead Frame for Semiconductor Devices having Improved Adhesive Bond Line Control” describes a similar approach. Four bumps inside the bond pad area are used instead of the boundary features at the edges. When the die is bonded onto the lead frame, the die would contact the bumps and a specific bond line thickness would be achieved. With the aid of such special lead frame designs, the bond line is guaranteed to be at least of a certain thickness. This prevents the problems faced when a thin bond line is too thin. However, there is still no control on avoiding a bond line that is too thick.

### SUMMARY OF THE INVENTION

It is thus an object of the invention to seek to provide an online bond line thickness measurement method, so that the bonded die samples do not need to be removed from the die-attach platform in order to measure bond line thickness.

It is a related object of the invention to seek to utilise the online measurement results to control a thickness of a bond line during die attachment.

According to a first aspect of the invention, there is provided a method for manufacturing a semiconductor package comprising the step of attaching a semiconductor die to a substrate on a process platform, the step of attaching the semiconductor die onto the substrate further comprising the steps of: dispensing an adhesive with a dispenser onto the substrate; bonding the semiconductor die onto the adhesive which has been dispensed onto the substrate with a bonding tool; and thereafter measuring a bond line thickness between a bottom surface of the semiconductor die and a top surface of the substrate on the process platform using a measuring device.

According to a second aspect of the invention, there is provided a die-attach apparatus for manufacturing a semiconductor package, the die-attach apparatus comprising: a dispenser for dispensing an adhesive onto a substrate; a bonding tool for bonding a semiconductor die onto the adhesive which has been dispensed onto the substrate; and a measuring device for measuring a bond line thickness between a bottom surface of the semiconductor die and a top surface of the substrate.

It will be convenient to hereinafter describe the invention in greater detail by reference to the accompanying drawings. The particularity of the drawings and the related description is not to be understood as superseding the generality of the broad identification of the invention as defined by the claims.

### BRIEF DESCRIPTION OF THE DRAWINGS

An example of an apparatus and method in accordance with the invention will now be described with reference to the accompanying drawings, in which:

FIG. 1 is a cross-sectional view of a semiconductor die which is attached onto a lead frame by an adhesive;

FIG. 2 is a schematic diagram illustrating a die-attach apparatus incorporating a bond line thickness control system according to the preferred embodiment of the invention;

FIG. 3 is a top view of a die attached onto a bond pad which indicates exemplary points for laser displacement measurement on the die and bond pad respectively;

FIG. 4 is an illustration of how laser displacement measurement may be conducted according to the preferred embodiment of the invention; and

FIG. 5 is a work-flow of an online bond line thickness measurement and control process according to the preferred embodiment of the invention.

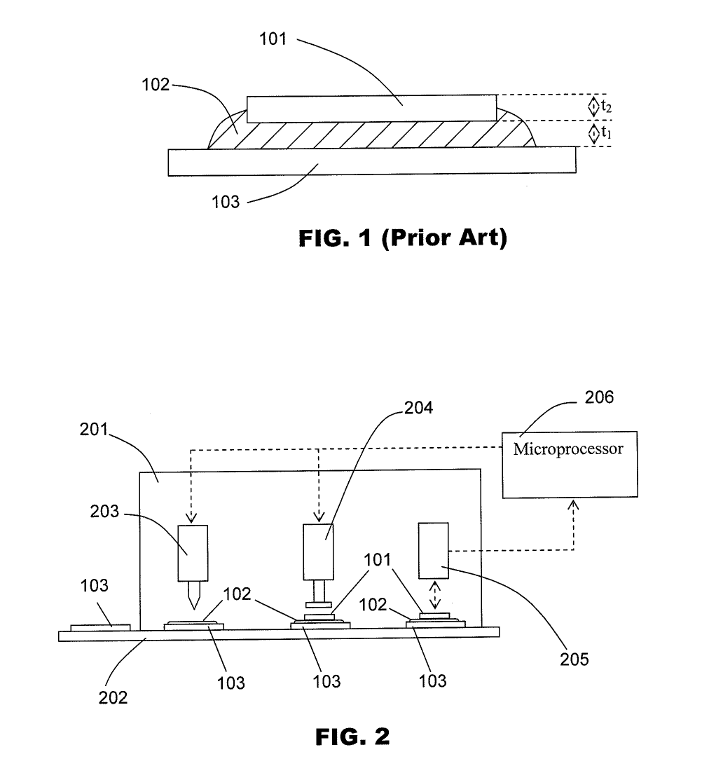

### DETAILED DESCRIPTION OF THE PREFERRED EMBODIMENT OF THE INVENTION

FIG. 2 is a schematic diagram illustrating a die-attach apparatus 201 incorporating a bond line thickness control system according to the preferred embodiment of the invention.

The die-attach apparatus 201 includes a process platform 202, an adhesive dispenser 203, a die bonding tool 204 and a measuring device such as a laser displacement sensor 205. The adhesive dispenser 203, die bonding tool 204 and laser displacement sensor 205 are located at different locations on the process platform 202. Thus, a conveyor is operative to transport a substrate successively to the respective locations during a die-attach operation.

During the die-attach operation, the substrate, which may be in the form of a lead frame 103, is transported along the platform 202. First, the lead frame 103 is positioned at the location of the adhesive dispenser 203 for dispensing an adhesive 102 onto the lead frame 103. Next, the lead frame 103 on which the adhesive 102 has been dispensed is forwarded to a location of the die bonding tool 204 for bonding a semiconductor die 101 onto the adhesive 102 which has been dispensed onto the lead frame 103. Then, the bonded lead frame 103 is moved to a post-bond location, whereat the laser displacement sensor 205 is mounted. The laser sensor 205 is operative to measure a difference in height between the die surface and the lead frame surface in order to measure the bond line thickness or BLT between a bottom surface of the die 101 and a top surface of the lead frame 103.

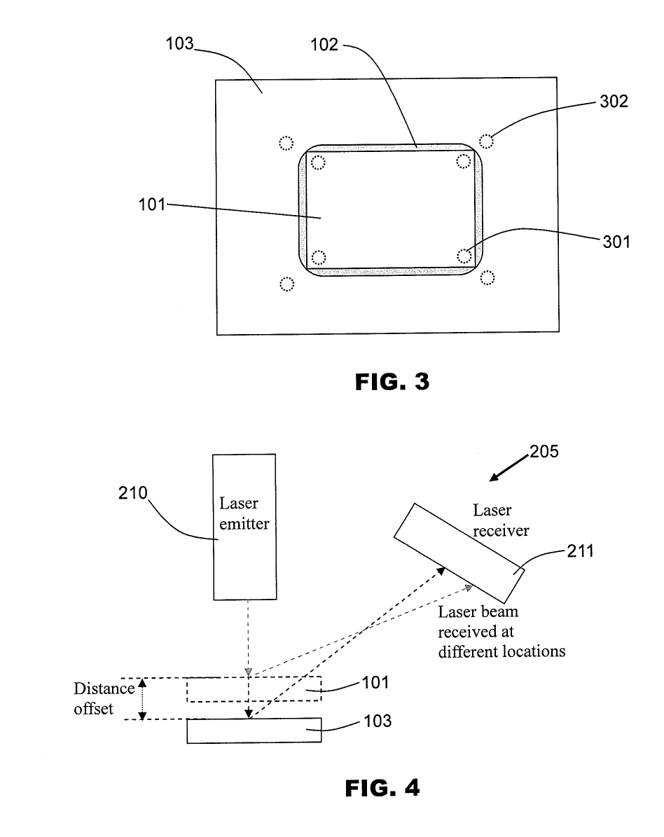

FIG. 3 is a top view of a die 101 attached onto a bond pad of a lead frame 103 which indicates exemplary points 301, 302 for laser displacement measurement on the die and bond pad respectively. It illustrates that the laser sensor 205 obtains readings from multiple points at several areas of the die 101 surface and the bond pad surface of the lead frame 103. In this example, readings are obtained at four corners 301 of the die surface and another four readings 302 are obtained at the bond pad. Hence, an average BLT can be obtained for the whole bonded die 101. The BLT is calculated by subtracting the height of the top surface of the lead frame 103 and a thickness of the die 101 from the height of the top surface of the die 101. Any die tilt can also be monitored from differences in height at the four corners 301 on the surface of the die 101. After the laser measurement, the bonded lead frame 103 is moved away from the die-attach apparatus 201 for oven curing.

Thus, the laser displacement sensor 205 is employed at the post-bond location of the die-attach apparatus 201. The displacement readings of the die surface and the lead frame surface are measured immediately after the die 101 is bonded. The BLT can then be calculated via a processor, such as a microprocessor 206, which is electrically connected to the laser displacement sensor 205, adhesive dispenser 203 and die bonding tool 204. Based on the results of the BLT measurement, process parameters are adjusted online in order to control the BLT within an appropriate range.

FIG. 4 is an illustration of how laser displacement measurement may be conducted according to the preferred embodiment of the invention. The preferred laser displacement sensor 205 used in the current invention employs the technique of laser triangulation for distance measurement. The laser displacement sensor 205 consists of the two main components: a laser emitter 210 and a laser receiver 211. The technique is termed as triangulation because the laser emitter 210, the laser receiver 211 and the object 101, 103 measured are arranged to form a triangle during the measurement (as demonstrated in FIG. 4). A laser beam is first emitted from the laser emitter 210 onto the object. The laser beam is reflected at the object surface, and the laser receiver 211 then captures the reflected beam. As the distance offset between the laser displacement sensor 205 and the object surface changes the laser reflection angle, the reflected laser beam would be detected at different locations of the laser receiver 211. Based on the location difference detected at the laser receiver 211, the height offset between the surface of the die 101 and the surface of the lead frame 103 can be determined.

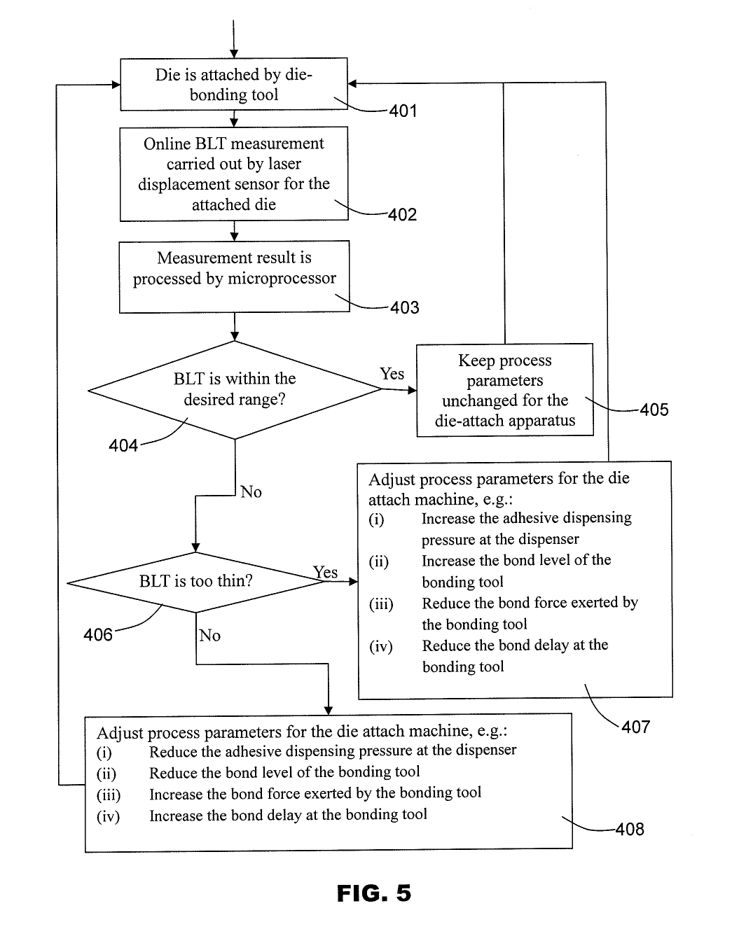

FIG. 5 is a work-flow of an online BLT measurement and control process according to the preferred embodiment of the invention which is implementable on the die-attach apparatus 201. A die 101 is bonded by a die-bonding tool 401, and the measurement of the relative height displacement between the die surface and the lead frame surface 402 is carried out by the laser displacement sensor 205 for the bonded die 101. This data is then processed 403 by the microprocessor 206, which calculates the BLT based on the displacement between the die and lead frame surfaces less the die thickness. According to the BLT, the microprocessor 206 determines whether the bond line is within a predetermined desired range of thickness 404. If so, the process parameters are kept unchanged 406. Online feedback control is established via the microprocessor 206. If the BLT is too thin or too thick 306, online corrective adjustment would be required. Corrective adjustment is thereafter fed back to corresponding modules such as the adhesive dispenser 203 and bonding tool 204, and corrective adjustments are carried out 307, 308.

As indicated in FIG. 5, the possible corrective adjustments include increasing or decreasing the adhesive dispensing pressure to control the amount of adhesive dispensed, increasing or decreasing the bond level at the bonding tool to control the vertical level for the die and adhesive contact, increasing or decreasing the bond force to control the depth for the die being pressed into the adhesive, and/or increasing or decreasing the bond delay to control the time for the die being pressed. Different trigger situations may also be catered for before triggering the corrective adjustments. For instance, the system may be set such that corrective adjustments are only triggered when the BLT is out of the desired range, or when the BLT is still inside the desired range but is outside a safety margin.

It should be appreciated that the die-attach apparatus 201 according to the preferred embodiment of the invention allows the BLT to be controlled in real time. There is no need to remove the bonded die for measuring the BLT or to design special lead frames for the purpose of BLT control. Hence, the said die-attach apparatus 201 helps to improve the yield and quality of the die-attach process.

The invention described herein is susceptible to variations, modifications and/or additions other than those specifically described and it is to be understood that the invention includes all such variations, modifications and/or additions which fall within the spirit and scope of the above description.

1. Method for manufacturing a semiconductor package comprising the step of attaching a semiconductor die onto a substrate on a process platform, the step of attaching the semiconductor die onto the substrate further comprising the steps of:
dispensing an adhesive with a dispenser onto the substrate;
bonding the semiconductor die onto the adhesive which has been dispensed onto the substrate with a bonding tool; and thereafter
measuring a bond line thickness between a bottom surface of the semiconductor die and a top surface of the substrate on the process platform using a measuring device.

2. Method as claimed in claim 1, wherein the steps of dispensing the adhesive, mounting the semiconductor die and measuring the bond line thickness are conducted at different locations on the process platform, and the method further comprises the step of moving the substrate successively to the respective locations.

3. Method as claimed in claim 1, wherein the measuring device measures a height of a top surface of the semiconductor die and a height of the top surface of the substrate.

4. Method as claimed in claim 3, further comprising the step of calculating the bond line thickness by subtracting the height of the top surface of the substrate and a thickness of the semiconductor die from the height of the top surface of the semiconductor die.

5. Method as claimed in claim 3, wherein readings at multiple points are taken of the height of the top surface of the semiconductor die and the height of the top surface of the substrate respectively.

6. Method as claimed in claim 5, further comprising the step of detecting whether the die is tilted with respect to the substrate.

7. Method as claimed in claim 3, wherein the measuring device comprises a laser displacement sensor.

8. Method as claimed in claim 7, wherein the laser displacement sensor measures the respective heights by distance measurement via laser triangulation using a laser emitter and a laser receiver.

9. Method as claimed in claim 1, further comprising the step of adjusting process parameters for attaching the semiconductor die to the substrate with a processor connected to the measuring device to maintain the bond line thickness within a desired range.

10. Method as claimed in claim 9, wherein the process parameters adjusted are the amount of adhesive dispensed and/or bonding level to which the semiconductor die is bonded.

11. Method as claimed in claim 9, wherein the process parameters adjusted are the bond force applied on the semiconductor die and/or a bond delay to control a duration of a bond force applied on the semiconductor die.

12. Method for attaching a semiconductor die onto a substrate on a process platform, comprising the steps of:
dispensing an adhesive with a dispenser onto the substrate;
bonding the semiconductor die onto the adhesive which has been dispensed onto the substrate with a bonding tool; and thereafter
measuring a bond line thickness between a bottom surface of the semiconductor die and a top surface of the substrate on the process platform using a measuring device.

13. A die-attach apparatus for manufacturing a semiconductor package, the die-attach apparatus comprising:
a dispenser for dispensing an adhesive onto a substrate;
a bonding tool for bonding a semiconductor die onto the adhesive which has been dispensed onto the substrate; and
a measuring device for measuring a bond line thickness between a bottom surface of the semiconductor die and a top surface of the substrate.

14. The die-attach apparatus as claimed in claim 13, wherein the dispenser, bonding tool and measuring apparatus are located at different locations, and the die-attach apparatus further comprises a conveyor for moving the substrate successively to the respective locations.

15. The die-attach apparatus as claimed in claim 13, wherein the measuring device is operative to measure a height of a top surface of the semiconductor die and a height of the top surface of the substrate.

16. The die-attach apparatus as claimed in claim 15, wherein the bond line thickness is calculated by subtracting the height of the top surface of the substrate and a thickness of the semiconductor die from the height of the top surface of the semiconductor die.

17. The die-attach apparatus as claimed in claim 15, wherein the measuring device comprises a laser displacement sensor.

18. The die-attach apparatus as claimed in claim 13, further comprising a processor connected to the measuring device that is operative to adjust process parameters for attaching the semiconductor die onto the substrate to maintain the bond line thickness within a desired range.

19. The die-attach apparatus as claimed in claim 18, wherein the process parameters adjusted are the amount of adhesive dispensed and/or bonding level to which the semiconductor die is bonded.

20. The die-attach apparatus as claimed in claim 18, wherein the process parameters adjusted are the bond force applied on the semiconductor die and/or a bond delay to control a duration of a bond force applied on the semiconductor die.
